(19) United States
(12) Patent Application Publication
(10) Pub. No.: US 2026/0033219 A1
(43) Pub. Date: Jan. 29, 2026

(54) DISPLAY SUBSTRATE AND METHOD FOR MANUFACTURING SAME, AND DISPLAY DEVICE

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Jianming ZOU, Beijing (CN); Dongdong SU, Beijing (CN); Ruquan LI, Beijing (CN); Bingming FENG, Beijing (CN); Yinhu HUANG, Beijing (CN); Jixing WANG, Beijing (CN); Fushuang ZHANG, Beijing (CN); Haojie YUAN, Beijing (CN); Shuanghong WU, Beijing (CN)

(21) Appl. No.: 18/994,590

(22) PCT Filed: May 28, 2024
(86) PCT No.: PCT/CN2024/095854

§ 371 Date: Jan. 14, 2025

(30) Foreign Application Priority Data
May 30, 2023 (CN) 202310627137.9

(51) Int. Cl. H10K 59/80; H10K 59/12; H10K 59/35

(52) U.S. Cl. CPC H10K 59/876; H10K 59/1201; H10K 59/353

(57) ABSTRACT

Provided is a display substrate. The display substrate includes: a base substrate; and a plurality of subpixels on the base substrate, each of the plurality of subpixels having a microcavity structure including a microcavity underlayer, wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure including the microcavity underlayer to meet a constructive interference condition of the light of any color.

### CROSS-REFERENCE TO RELATED APPLICATION

This application is a U.S. national stage of international application No. PCT/CN2024/095854, filed on May 28, 2024, which claims priority to Chinese Patent Application No. 202310627137.9, filed on May 30, 2023 and entitled “DISPLAY SUBSTRATE AND PREPARATION METHOD THEREFOR, AND DISPLAY DEVICE,” the disclosures of which are herein incorporated by references in their entireties.

### TECHNICAL FIELD

The present disclosure relates to the technical field of display, and in particular, relates to a display substrate and a method for manufacturing the same, and a display device.

### BACKGROUND

Quantum dot light-emitting diodes (QLEDs) are organic thin-film electroluminescent devices, and have advantages of simple manufacturing process, low cost, high luminous efficiency, and tending to a flexible structure. Thus, a display technology using the OLED is a critical in the display field.

### SUMMARY

Embodiments of the present disclosure provide a display substrate and a method for manufacturing the same, and a display device. The technical solutions are as follows.

Some embodiments of the present disclosure provide a display substrate. The display substrate includes:
a base substrate; and
a plurality of subpixels on the base substrate, each of the plurality of subpixels having a microcavity structure including a microcavity underlayer,
wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure including the microcavity underlayer to meet a constructive interference condition of the light of any color.

In some embodiments, the refractive index of the microcavity underlayer in the any of the plurality of subpixels and a wavelength of the light of the color corresponding to the any of the plurality of subpixels meet:

$$A + n \times d = k \times \frac{λ}{2} ;$$

wherein A represents an optical path in the microcavity structure other than the microcavity underlayer in the any of the plurality of subpixels, the microcavity structures of the plurality of subpixels have a same A, n represents the refractive index of the microcavity underlayer in the any of the plurality of subpixels, d represents a thickness of the microcavity underlayer in the any of the plurality of subpixels, k is a positive integer, and λ represents the wavelength of the light of the color corresponding to the any of the plurality of subpixels.

In some embodiments, thicknesses of the microcavity underlayers in the plurality of subpixels are the same.

In some embodiments, materials of the microcavity underlayers in the subpixels corresponding to the light of different colors are the same or different.

In some embodiments, in a case that the materials of the microcavity underlayers in the subpixels corresponding to the light of different colors are the same, different particles are doped in the microcavity underlayers in the subpixels corresponding to the light of different colors.

In some embodiments, each of the plurality of subpixels further includes:
an undercut structure on a side of the microcavity underlayer in the each of the plurality of subpixels away from the base substrate, wherein the undercut structure includes a recess portion, and
the undercut structure includes a first material layer and a second material layer, wherein the first material layer is disposed on a side of the second material layer away from the base substrate, and an orthographic projection of a surface of the first material layer enclosing the recess portion on the base substrate is within an orthographic projection of a surface of the second material layer enclosing the recess portion on the base substrate.

In some embodiments, an etching rate in the first material layer is less than an etching rate in the second material layer.

In some embodiments, the first material layer and the second material layer meet any of the following conditions:
a material of the first material layer is the same as a material with a lowest etching rate in materials of the microcavity underlayers in the plurality of subpixels, and a material of the second material layer is different from the material with the lowest etching rate in the materials of the microcavity underlayers in the plurality of subpixels; and
the material of the first material layer is different from a material with a highest etching rate in the materials of the microcavity underlayers in the plurality of subpixels, and the material of the second material layer is the same as the material with the highest etching rate in the materials of the microcavity underlayers in the plurality of subpixels.

In some embodiments, the plurality of subpixels include a first subpixel and a second subpixel, wherein the first subpixel is a blue subpixel, and the second subpixel is a green subpixel; a material of a microcavity underlayer in the first subpixel includes silicon oxide, and a material of a microcavity underlayer in the second subpixel includes silicon nitride; and
a material of the first material layer includes silicon oxide, and a material of the second material layer includes silicon nitride.

In some embodiments, the display substrate further includes: a peripheral region surrounding the plurality of subpixels, wherein the peripheral region includes a first silicon oxide layer, a first silicon nitride layer, a second silicon nitride layer, and a second silicon oxide layer that are sequentially stacked; and
the plurality of subpixels include a first subpixel and a second subpixel, and each of the plurality of subpixels further includes an undercut structure on a side of the microcavity underlayer in the each of the plurality of subpixels away from the base substrate, wherein the undercut structure includes a recess portion, and the undercut structure includes a first material layer and a second material layer, wherein the first material layer is disposed on a side of the second material layer away from the base substrate, and an orthographic projection of a surface of the first material layer enclosing the recess portion on the base substrate is within an orthographic projection of a surface of the second material layer enclosing the recess portion on the base substrate;
wherein the first silicon oxide layer and a microcavity underlayer in the first subpixel are disposed on a same layer, the first silicon nitride layer and a microcavity underlayer in the second subpixel are disposed on a same layer, the second silicon nitride layer and the second material layer are disposed on a same layer, and the second silicon oxide layer and the first material layer are disposed on a same layer.

In some embodiments, each of the plurality of subpixels further includes:
a reflective electrode layer between the base substrate and the microcavity underlayer;
a reflective electrode protection layer between the reflective electrode layer and the microcavity underlayer; and
a light-emitting layer and a semitransparent electrode layer that are sequentially stacked on a side of the undercut structure away from the base substrate;
wherein the microcavity structure of each of the plurality of subpixels is formed between the reflective electrode layer and the semitransparent electrode layer, and the plurality of subpixels meet: a condition that thicknesses, refractive indexes, or both of the reflective electrode layers in the plurality of subpixels are the same, a condition that thicknesses, refractive indexes, or both of the light-emitting layers in the plurality of subpixels are the same, a condition that thicknesses, refractive indexes, or both of the semitransparent electrode layers in the plurality of subpixels are the same, or any combination of the conditions.

In some embodiments, a via is defined in the microcavity underlayer in each of the plurality of subpixels, wherein a conductive material is filled in the via, the conductive material being configured to electrically connect structures on two sides of the microcavity underlayer.

In some embodiments, a taper of the via is less than 45°.

Some embodiments of the present disclosure provide a display device. The display device includes: a display substrate, wherein the display substrate includes:
a base substrate; and
a plurality of subpixels each having a microcavity structure, wherein the plurality of subpixels are disposed on the base substrate, and the microcavity structure in each of the plurality of subpixels includes a microcavity underlayer,
wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure including the microcavity underlayer to meet a constructive interference condition of the light of any color.

Some embodiments of the present disclosure provide a display substrate. The display substrate includes:
providing a base substrate; and
forming a plurality of subpixels on the base substrate, each of the plurality of subpixels having a microcavity structure including a microcavity underlayer,
wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure including the microcavity underlayer to meet a constructive interference condition of the light of any color.

In some embodiments, forming the plurality of subpixels on the base substrate includes:
forming reflective electrode layers of the plurality of subpixels on the base substrate;
sequentially forming the microcavity underlayers of the plurality of subpixels on a side of the reflective electrode layers of the plurality of subpixels away from the base substrate using materials of the microcavity underlayers of the plurality of subpixels; and
sequentially forming light-emitting layers and semitransparent electrode layers of the plurality of subpixels on a side of the microcavity underlayers of the plurality of subpixels away from the base substrate, such that the plurality of subpixels are acquired, wherein the microcavity structure of any of the plurality of subpixels is formed between the reflective electrode layer and the semitransparent electrode layer of the any of the plurality of subpixels.

In some embodiments, sequentially forming the microcavity underlayers of the plurality of subpixels on the side of the reflective electrode layers of the plurality of subpixels away from the base substrate using the materials of the microcavity underlayers of the plurality of subpixels includes:
sequentially forming the microcavity underlayers of the plurality of subpixels on the side of the reflective electrode layers of the plurality of subpixels away from the base substrate using the materials of the microcavity underlayers of the plurality of subpixels in an ascending order of etching rates of the materials of the microcavity underlayers of the plurality of subpixels.

In some embodiments, the plurality of subpixels include a first subpixel and a second subpixel, and an etching rate in a material of a microcavity underlayer in the first subpixel is less than an etching rate in a material of a microcavity underlayer in the second subpixel; and sequentially forming the microcavity underlayers of the plurality of subpixels on the side of the reflective electrode layers of the plurality of subpixels away from the base substrate using the materials of the microcavity underlayers of the plurality of subpixels in the ascending order of the etching rates of the materials of the microcavity underlayers of the plurality of subpixels includes:
forming a first material film on the side of the reflective electrode layers of the plurality of subpixels away from the base substrate using the material of the microcavity underlayer in the first subpixel;
forming the microcavity underlayer in the first subpixel by etching the first material film;
upon forming the microcavity underlayer in the first subpixel, forming a second material film on the side of the reflective electrode layers of the plurality of subpixels away from the base substrate using the material of the microcavity underlayer in the second subpixel; and
forming the microcavity underlayer in the second subpixel by etching the second material film.

In some embodiments, a ratio of the etching rate in the material of the microcavity underlayer in the first subpixel to the etching rate in the material of the microcavity underlayer in the second subpixel is less than or equal to a predetermined ratio threshold; and
the material of the microcavity underlayer in the first subpixel includes silicon oxide, and the material of the microcavity underlayer in the second subpixel includes silicon nitride.

In some embodiments, upon sequentially forming the microcavity underlayers of the plurality of subpixels on the side of the reflective electrode layers of the plurality of subpixels away from the base substrate using the materials of the microcavity underlayers of the plurality of subpixels, and prior to sequentially forming the light-emitting layers and the semitransparent electrode layers of the plurality of subpixels on the side of the microcavity underlayers of the plurality of subpixels away from the base substrate, the method further includes:
forming second material layers on the side of the microcavity underlayers of the plurality of subpixels away from the base substrate using a material with a highest etching rate in the materials of the microcavity underlayers in the plurality of subpixels;
forming first material layers on the side of the second material layers of the plurality of subpixels away from the base substrate using a material with a smallest etching rate in the materials of the microcavity underlayers in the plurality of subpixels; and
forming undercut structures of the plurality of subpixels by etching the first material layers and the second material layers of the plurality of subpixels, wherein each of the undercut structures includes a recess portion, and an orthographic projection of a surface of each of the first material layers enclosing the recess portion on the base substrate is within an orthographic projection of a surface of one of the second material layers enclosing the recess portion on the base substrate.

### BRIEF DESCRIPTION OF DRAWINGS

FIG. 1 is a schematic diagram of a microcavity structure of a subpixel;

FIG. 2 is a schematic structural diagram of a display substrate in some practices;

FIG. 3 is a schematic structural diagram of a display substrate according to some embodiments of the present disclosure;

FIG. 4 is a schematic structural diagram of a subpixel according to some embodiments of the present disclosure;

FIG. 5 is a schematic structural diagram of a subpixel according to some embodiments of the present disclosure;

FIG. 6 is a schematic structural diagram of a subpixel according to some embodiments of the present disclosure;

FIG. 7 is a flowchart of a method for manufacturing a display substrate according to some embodiments of the present disclosure;

FIG. 8 is a flowchart of a method for manufacturing a display substrate according to some embodiments of the present disclosure;

FIG. 9 is a schematic diagram of formation of a display substrate according to some embodiments of the present disclosure;

FIG. 10 is a schematic diagram of formation of a display substrate according to some embodiments of the present disclosure;

FIG. 11 is a schematic diagram of formation of a display substrate according to some embodiments of the present disclosure;

FIG. 12 is a schematic diagram of formation of a display substrate according to some embodiments of the present disclosure;

FIG. 13 is a schematic diagram of formation of a display substrate according to some embodiments of the present disclosure;

FIG. 14 is a schematic diagram of formation of a display substrate according to some embodiments of the present disclosure;

FIG. 15 is a schematic diagram of formation of a display substrate according to some embodiments of the present disclosure;

FIG. 16 is a schematic diagram of formation of a display substrate according to some embodiments of the present disclosure;

FIG. 17 is a schematic diagram of formation of a display substrate according to some embodiments of the present disclosure;

FIG. 18 is a schematic diagram of formation of a display substrate according to some embodiments of the present disclosure;

FIG. 19 is a schematic diagram of formation of a display substrate according to some embodiments of the present disclosure;

FIG. 20 is a schematic diagram of formation of a display substrate according to some embodiments of the present disclosure;

FIG. 21 is a schematic diagram of formation of a display substrate according to some embodiments of the present disclosure;

FIG. 22 is a schematic diagram of formation of a display substrate according to some embodiments of the present disclosure; and

FIG. 23 is a schematic diagram of formation of a display substrate according to some embodiments of the present disclosure.

### DETAILED DESCRIPTION

The technical solutions according to the embodiments of the present disclosure are described clearly and completely hereinafter in combination with the accompanying drawings in the embodiments of the present disclosure. It is obvious that the described embodiments are merely part but not all of the embodiments of the present disclosure. All other embodiments derived by those skilled in the art without creative efforts based on the embodiments in the present disclosure are within the protection scope of the disclosure.

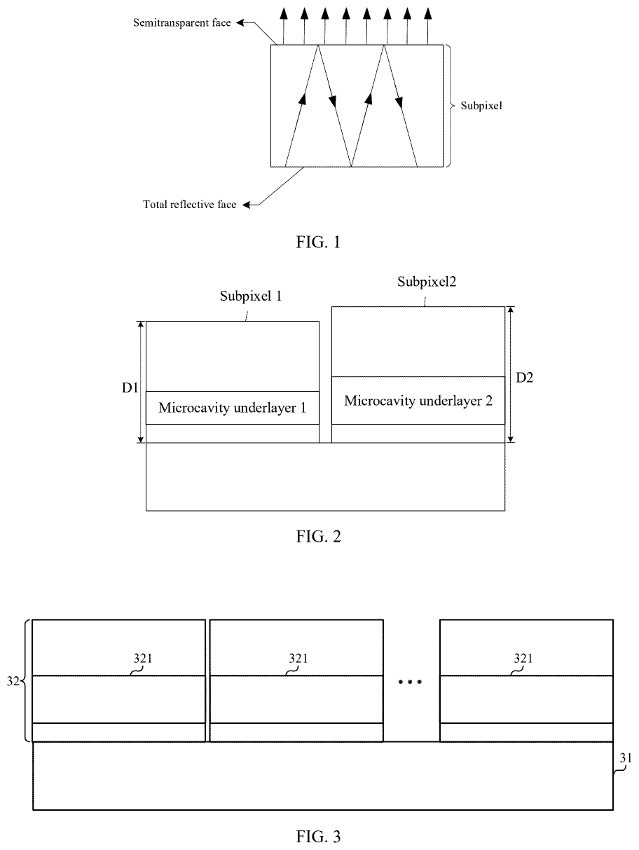

The microcavity effect is used in the OLED product to enhance the luminous efficacy and improve the display effect of the OLED product. For example, a plurality of subpixels in the display substrate in the OLED product have the microcavity structures, and the microcavity structures in the subpixels are used to meet a constructive interference condition of the light wave to enhance the luminous efficacy of the light wave. The constructive interference condition of light wave is that an optical path of light in the microcavity structure is an integral times of a half wavelength of the light wave. FIG. 1 is a schematic diagram of a microcavity structure of a subpixel according to the present disclosure. As shown in FIG. 1, the microcavity structure includes a total reflective face and a semitransparent face (also referred to as a luminous layer of the subpixel). In the microcavity structure, after the light wave reaches the semitransparent face of the subpixel, part of the light wave is transmitted, such that the microcavity structure includes the constantly oscillating light wave. In the case that the optical path between the total reflective face and the semitransparent face is an integral times of the half wavelength of the light wave, the luminous efficacy of the light wave in the microcavity structure is enhanced as the constructive interference condition is met.

At present, a thickness of the microcavity structure is adjusted by adjusting a thickness of the microcavity underlayer in each of the plurality of subpixels, such that the microcavity structure in each of the plurality of subpixels meets the constructive interference condition. As shown in FIG. 2, the display substrate includes a subpixel 1 and a second subpixel 2. A wavelength of light emitted by the subpixel 1 is less than a wavelength of light emitted by the subpixel 2. The microcavity structure in the subpixel 1 includes a microcavity underlayer 1, and the microcavity structure in the subpixel 2 includes a microcavity underlayer 2. A thickness of the microcavity underlayer 1 is less than a thickness of the microcavity underlayer 2, such that a thickness D1 of the microcavity structure in the subpixel 1 is less than a thickness D2 of the microcavity structure in the subpixel 2.

However, due to the difference in wavelength of light emitted by subpixels emitting light of different colors, the microcavity structures in the subpixels emitting light of different colors have inconsistent thicknesses in the case that the microcavity structures meet the constructive interference condition by adjusting the thickness of the microcavity structure. Moreover, due to the light absorption effect, light absorption capacities of the microcavity structures with different thicknesses are different, such that the thickness of the microcavity structure affects the luminous efficacy. Therefore, luminous efficacies of subpixels emitting light of different colors are different, such that display uniformity of the plurality of subpixels is poor.

The embodiments of the present disclosure provide a display substrate to reduce differences in luminous efficacies of the plurality of subpixels emitting light of different colors and improve the display uniformity of the plurality of subpixels. As shown in FIG. 3, the display substrate according to the embodiments of the present disclosure includes:
a base substrate 31; and
a plurality of subpixels 32 on the base substrate 31. Each of the plurality of subpixels has a microcavity structure, and the microcavity structure includes a microcavity underlayer 321.

Refractive indexes of microcavity underlayers 321 in subpixels 32 corresponding to light of different colors are different, a refractive index of the microcavity underlayer 321 in any of the plurality of subpixels 32 matches light of a color corresponding to the any of the plurality of subpixels 32, and a refractive index of the microcavity underlayer matched with light of any color causes the microcavity structure including the microcavity underlayer to meet a constructive interference condition of the light of any color. The any of the plurality of subpixels refers to any of the plurality of subpixels in the display substrate.

The display substrate 100 is, for example, an OLED, a micro light-emitting diode (micro LED for short) display substrate, a mini light-emitting diode display substrate, a silicon-based OLED, and the like, which is not specifically limited in the present disclosure. In some embodiments, the based substrate 31 is a rigid base substrate or a flexible base substrate. A material of the rigid base substrate includes glass, quartz, plastic, or the like. A materials of the flexible base substrate includes polyethylene terephthalate (PET), polyethylene naphthalate (PEN), polyimide (PI), or the like.

The plurality of subpixels in the display substrate include various types of subpixels, and colors of light corresponding to different types of subpixels are colors required to be displayed by the subpixels. For example, the display substrate includes red (R) subpixels, green (G) subpixels, and blue (B) subpixels. The light of the color required to be displayed by the red subpixel is red light, with a wavelength range of from 622 nanometers (nm) to 760 nm. The light of the color required to be displayed by the green subpixel is green light, with a wavelength range from 492 nm to 577 nm. The light of the color required to be displayed by the blue subpixel is blue light, with a wavelength range from 435 nm to 450 nm. The plurality of subpixels 32 are disposed on the base substrate 31. That is, the plurality of subpixels 32 are directly disposed on the base substrate 31, or an intermediate layer is present between the plurality of subpixels 32 and the base substrate 31.

In some embodiments, the microcavity structure includes a total reflective face and a semitransparent face. That is, the subpixel including the microcavity structure includes the total reflective face and the semitransparent face, and an optical path between the total reflective face and the semitransparent face meets the constructive interference condition of the light of the color emitted by the subpixel. In some embodiments, the total reflective face is a face of the reflective electrode layer away from the base substrate, and the reflective electrode layer is, for example, an anode made of aluminum (Al), titanium (Ti), argentum (Ag), and the like. The semitransparent face is a face of the semitransparent electrode layer close to the base substrate, and the semitransparent electrode layer includes a plurality of material layers with different refractive indexes, for example, formed by metal and dielectric multilayers, which are not specifically limited in the present disclosure.

Due to different wavelengths of light of colors corresponding to different subpixels in the display substrate, optical paths of the light of the colors emitted by different subpixels are different, such that the luminous efficiencies are enhanced in different subpixels using the microcavity effect. At present, the refractive indexes of various structural layers in the microcavity structures of different subpixels in the display substrate are the same. For enhancement of the display effect in different subpixels using the microcavity effect, the optical paths of the microcavity structures of different subpixels are adjusted by adjusting the thicknesses of the microcavity structures of different subpixels in the case that the refractive indexes of various structural layers are the same. For example, the microcavity structures of the plurality of subpixel include the microcavity underlayers, and the thicknesses of the microcavity structures of the subpixels is adjusted by adjusting the thicknesses of the microcavity underlayers of the subpixels. In the embodiments, as the thicknesses of the microcavity structures in different subpixels are different, and the thicknesses of the microcavity structures affect the luminous efficiencies, the luminous efficiencies of different subpixels are different, and the display uniformity of the plurality of subpixels is poor.

For improvement of the display uniformity of the plurality of subpixels, in the embodiments of the present disclosure, the refractive indexes of the microcavity underlayers in the plurality of subpixels 32 in the display substrate are different, and the refractive index of the microcavity underlayer in any subpixel 32 matches the wavelength of the light of the color corresponding to the any subpixel 32. A refractive index of the microcavity underlayer matched with light of any color causes the microcavity structure including the microcavity underlayer to meet the constructive interference condition of the light of any color. As the refractive indexes of the microcavity underlayers in different subpixels are different, the microcavity structures of the subpixels corresponding to light of different colors meet the constructive interference conditions of the light of corresponding colors. The optical path is a product of the refractive index and the thickness of the medium. Thus, compared with the method of adjusting the thickness of the microcavity underlayer in the case that the refractive indexes of the microcavity underlayers in the plurality of subpixels are the same, the thickness of the microcavity underlayer is reduced by adjusting the refractive index of the microcavity underlayer in the present disclosure, such that the difference in thicknesses of the microcavity underlayers in the plurality of subpixels corresponding to light of the colors is reduced, the difference in the microcavity structures in the subpixels is reduced, the difference in the luminous efficiencies of the subpixels is reduced, and the display uniformity of the plurality of subpixels is improved.

In some embodiments, the refractive index of the microcavity underlayer in the any subpixel and a wavelength of the light of the color corresponding to the any subpixel meet:

$$A + n \times d = k \times \frac{λ}{2} .$$

A represents the optical path in the microcavity structure other than the microcavity underlayer in the subpixel. The microcavity structures of the plurality of subpixels have the same A, that is, optical paths in the microcavity structures other than the microcavity underlayers in the subpixels corresponding to light of different colors are the same. n represents the refractive index of the microcavity underlayer in the subpixel, d represents the thickness of the microcavity underlayer in the subpixel, k is a positive integer, and Λ represents the wavelength of the light of the color corresponding to the subpixel.

For example, the display substrate includes a subpixel 1 and a subpixel 2.

The wavelength of the light of the color emitted by the subpixel 1 is Λ1, refractive index of the microcavity underlayer in the microcavity structure is n1, and the thickness of the microcavity underlayer in the microcavity structure is d1. Thus,

$$A + n 1 \times d 1 = k \times \frac{λ 1}{2} .$$

The wavelength of the light of the color emitted by the subpixel 2 is Λ2, refractive index of the microcavity underlayer in the microcavity structure is n2, and the thickness of the microcavity underlayer in the microcavity structure is d2. Thus,

$$A + n 2 \times d 2 = k \times \frac{λ 2}{2} .$$

For the subpixel 1 and the subpixel 2, the optical paths in the microcavity structures other than the microcavity underlayers are the same, that is, the subpixel 1 and the subpixel 2 have the same A. thus, the subpixel 1 and the subpixel 2 meet the constraint by adjusting the refractive index and/or the thickness of the microcavity underlayer.

In some embodiments, the plurality of subpixels in the display substrate have the same k, and thus the refractive indexes of the microcavity underlayers in the plurality of subpixels are positively correlated with the wavelengths of light of colors corresponding to the plurality of subpixels. In the case that k is the same, the longer the wavelength of the light of the corresponding color, the greater the refractive index of the microcavity underlayer. For example, in the case that k is the same, the display substrate includes red subpixels, green subpixels, and blue subpixels. As the wavelength of red light is greater than the wavelength of green light, and the wavelength of green light is greater than the wavelength of blue light, the refractive index of the microcavity underlayer in the red subpixel is greater than the refractive index of the microcavity underlayer in the green subpixel, and the refractive index of the microcavity underlayer in the green subpixel is greater than the refractive index of the microcavity underlayer in the blue subpixel. As the optical path is the product of the refractive index and the thickness of the medium, compared with the case where the refractive indexes of the microcavity underlayers of the plurality of subpixels corresponding to light of different colors are the same, the difference in the thicknesses of the microcavity underlayers in the plurality of subpixels is reduced by adjusting the refractive indexes.

Currently, in some practices, the refractive indexes of the microcavity underlayers of the plurality of subpixels are the same, and thus the optical path of the light in the microcavity structure of the subpixel matches the wavelength of the light of the corresponding color by adjusting the optical path based on the thickness, which causes different thicknesses of different subpixels. On this basis, in the present disclosure, the optical path of the light in the microcavity structure of the subpixel matches the wavelength of the light of the corresponding color by adjusting the refractive index, such that the difference in the thicknesses of the plurality of subpixels is reduced, and the display uniformity of the plurality of subpixels corresponding to light of different colors is improved.

In some embodiments of the present disclosure, the optical path matches the wavelength by adjusting the refractive index. In this case, the thicknesses of the microcavity underlayers of the plurality of subpixels are the same, and reduction of the difference between the luminous efficiencies of different subpixels is maximized.

In some embodiments of the present disclosure, adjustment methods of the optical path are diversified by adjusting the thickness and the refractive index of the microcavity underlayer to match different service requirements. It should be noted that for the embodiments of the present disclosure, the refractive index of the microcavity underlayer in any subpixel is positively correlated with the wavelength of the light of the color corresponding to the subpixel, and thus even if the thicknesses of the microcavity underlayers in the microcavity structures of the plurality of subpixels are different, the difference is smaller than the difference in the thicknesses of the microcavity underlayers in the case of the same refractive index in some practices.

The material of the microcavity underlayer in the embodiments of the present disclosure are a material with an adjustable refractive index, such that the refractive index of the microcavity underlayer in the subpixel matches the wavelength of the light of the color corresponding to the subpixel. In some embodiments, the material with the adjustable refractive index includes silicon oxide (SiO), silicon nitride (SiN), aluminum oxide (A12O3), or any combination thereof. The refractive indexes of the above materials are adjusted by adjusting the filming parameters. For example, in preparing SiO, different particles are doped in the process of preparing SiO to adjust the refractive index of SiO. Alternatively, in preparing the microcavity underlayer, different particles are doped into the film formed by SiO to adjust the refractive index of the microcavity underlayer.

In some embodiments, the materials of the microcavity underlayers in the plurality of subpixels in the display substrate are the same. For example, the materials of the microcavity underlayers in the microcavity structures in the plurality of subpixels all are SiO, but the refractive indexes of the materials SiO of the microcavity underlayers in the microcavity structures in different subpixels are different. For example, different refractive indexes are achieved by doping different particles into SiO. In some embodiments, the materials of the microcavity underlayers in the plurality of subpixels in the display substrate are different. For example, the material of the microcavity underlayer in the green subpixel is SiN, and the material of the microcavity underlayer in the blue subpixel is SiO.

In some embodiments, due to different etching rates of different materials, in the case that the materials of the microcavity underlayers of different subpixels are different, the formation order of the microcavity underlayers in the subpixels corresponding to different colors are inversely proportional to the etching rates of the materials of the microcavity underlayers to reduce etching loss and avoid the fluctuation of the cavity length of the microcavity structure due to etching loss. In short, the slower the etching rate in the material, the more advanced the formation order of the microcavity underlayer formed by the material.

In some embodiments, the plurality of subpixels in the display substrate include a first subpixel and a second subpixel. The material of the microcavity underlayer in the first subpixel includes silicon oxide, and the material of the microcavity underlayer in the second subpixel includes silicon nitride. As the etching rate in the silicon oxide is less than the etching rate in the silicon nitride, the formation order of the microcavity underlayer in the first subpixel is earlier than the formation order of the microcavity underlayer in the second subpixel. That is, silicon oxide is used to form the microcavity underlayer in the first subpixel, and then silicon nitride is used to form the microcavity underlayer in the second subpixel. In some embodiments, the first subpixel is a blue subpixel, and the second subpixel is a green subpixel.

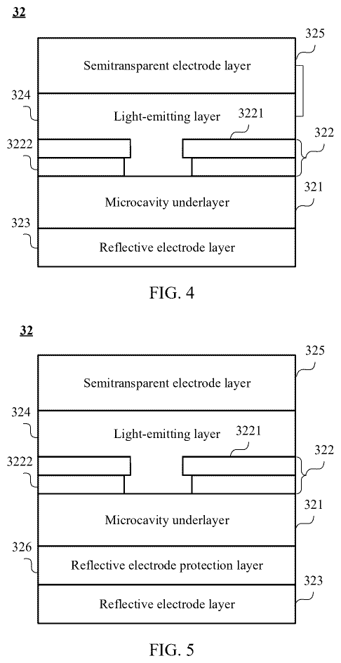

In some embodiments, for improvement of the stability of the structure of the subpixel, the subpixel 32 further includes an undercut structure on a side of the microcavity underlayer in the subpixel away from the base substrate. FIG. 4 is a schematic structural diagram of a subpixel according to some embodiments of the present disclosure. As shown in FIG. 4,, the subpixel 32 includes a microcavity underlayer 321 and an undercut structure 322. The undercut structure 322 undercut structure includes a first material layer 3221 and a second material layer 3222. The first material layer 3221 is disposed on a side of the second material layer 3222 away from the base substrate. The undercut structure 322 includes a recess portion. An orthographic projection of a surface of the first material layer enclosing the recess portion on the base substrate is within an orthographic projection of a surface of the second material layer enclosing the recess portion on the base substrate. Due to the undercut structure 322, after other structure layers are formed on the undercut structure 322, the other structure layers fills the recess portion of the undercut structure 322, such that stability of bonding between the other structure layers and the undercut structure 322 is improved.

For formation of the undercut structure 322, an etching rate in the first material layer is less than an etching rate in the second material layer. In some embodiments, a material of the first material layer 3221 in the undercut structure 322 of each subpixel 32 is the same as a material with a lowest etching rate in materials of the microcavity underlayers in the plurality of subpixels 32, and a material of the second material layer 3222 in the undercut structure 322 of each subpixel 32 is different from the material with the lowest etching rate in the materials of the microcavity underlayers in the plurality of subpixels 32. Illustratively, in the case that the plurality of subpixels include the first subpixel and the second subpixel, the material of the microcavity underlayer in the first subpixel is silicon oxide, and the material of the microcavity underlayer in the second subpixel is silicon nitride. As the etching rate in the silicon oxide is less than the etching rate in the silicon nitride, the material with the lowest etching rate in the materials of the microcavity underlayers in the plurality of subpixels is silicon oxide. In this case, the material of the first material layer is silicon oxide, and the material of the second material layer is silicon nitride.

In some embodiments, the material of the first material layer 3221 in the undercut structure 322 of each subpixel 32 is different from a material with a highest etching rate in the materials of the microcavity underlayers 321 in the plurality of subpixels 32, and the material of the second material layer 3222 in the undercut structure 322 of each subpixel 32 is the same as the material with the highest etching rate in the materials of the microcavity underlayers 321 in the plurality of subpixels 32. Illustratively, in the case that the plurality of subpixels include the first subpixel and the second subpixel, the material of the microcavity underlayer in the first subpixel is silicon oxide, and the material of the microcavity underlayer in the second subpixel is silicon nitride. As the etching rate in the silicon oxide is less than the etching rate in the silicon nitride, the material with the highest etching rate in the materials of the microcavity underlayers in the plurality of subpixels is silicon nitride. In this case, the material of the second material layer is silicon nitride, and the material of the first material layer is not silicon nitride.

Based on the above embodiments, the material of the first material layer 3221 in the undercut structure 322 of each subpixel 32 is the same as the material with the lowest etching rate in materials of the microcavity underlayers 321 in the plurality of subpixels 32, and the material of the second material layer 3222 in the undercut structure 322 of each subpixel 32 is the same as the material with the highest etching rate in the materials of the microcavity underlayers in the plurality of subpixels 32. Illustratively, in the case that the plurality of subpixels include the first subpixel and the second subpixel, the material of the microcavity underlayer in the first subpixel is silicon oxide, and the material of the microcavity underlayer in the second subpixel is silicon nitride. As the etching rate in the silicon oxide is less than the etching rate in the silicon nitride, the material with the lowest etching rate in the materials of the microcavity underlayers in the plurality of subpixels is silicon oxide, and the material with the highest etching rate in the materials of the microcavity underlayers in the plurality of subpixels is silicon nitride. In this case, the material of the first material layer is silicon oxide, and the material of the second material layer is silicon nitride.

As the material of the first material layer in the undercut structure of each subpixel is the same as the material with the lowest etching rate in the materials of the microcavity underlayers in the plurality of subpixels, and the material of the second material layer in the undercut structure of each subpixel is the same as the material with the highest etching rate in the materials of the microcavity underlayers in the plurality of subpixels, the formation order of the first material layer in the plurality of subpixels is later than the formation order of the second material layer to form a recess portion with small top and large bottom in the undercut structure, such that the first material layer is disposed on the side of the second material layer away from the base substrate. Meanwhile, in etching the recess portion, the etching rate in the first material layer is slow, the etching rate in the second material layer is faster, and thus the recess portion with small top and large bottom is formed.

On this basis, in addition to the subpixel, the display panel further includes a peripheral region surrounding the subpixels. The peripheral region includes all or part of material layers involved in the process of manufacturing the subpixels. In some embodiments, the peripheral region includes a first silicon oxide layer, a first silicon nitride layer, a second silicon nitride layer, and a second silicon oxide layer that are sequentially stacked. The first silicon oxide layer and the microcavity underlayer in the first subpixel are disposed on the same layer, the first silicon nitride layer and the microcavity underlayer in the second subpixel are disposed on the same layer, the second silicon nitride layer and the second material layer are disposed on the same layer, and the second silicon oxide layer and the first material layer are disposed on the same layer. Two film layers being on the same layer means that the two film layers are formed by the same lithography process.

Based on the above embodiments, as shown in FIG. 4, each subpixel 32 further includes a reflective electrode layer 323, a light-emitting layer 324, and a semitransparent electrode layer 325. The reflective electrode layer 323 is disposed between the base substrate 31 and the microcavity underlayer 321. The light-emitting layer 324 and the semitransparent electrode layer 325 are sequentially stacked on a side of the undercut structure 322 away from the base substrate 31. The microcavity structure is formed between the reflective electrode layer 323 and the semitransparent electrode layer 325.

The plurality of subpixels meet: a condition that thicknesses, refractive indexes, or both of the reflective electrode layers in the plurality of subpixels are the same, a condition that thicknesses, refractive indexes, or both of the light-emitting layers in the plurality of subpixels are the same, a condition that thicknesses, refractive indexes, or both of the semitransparent electrode layers in the plurality of subpixels are the same, or any combination of the conditions. In the case that thicknesses and refractive indexes of the reflective electrode layers in the plurality of subpixels are the same, thicknesses and refractive indexes of the light-emitting layers in the plurality of subpixels are the same, and thicknesses and refractive indexes of the semitransparent electrode layers in the plurality of subpixels are the same, total optical paths of the light wave in the plurality of subpixels running through the reflective electrode layers, the light-emitting layers, and the semitransparent electrode layers are the same, such that the total optical path of the subpixel is adjusted by adjusting the thickness and/or the refractive index of the microcavity underlayer to match the optical path of the light of the color emitted by the subpixel.

In some embodiments, in the case that the reflective electrode layer is made of a corrosion-prone material (for example, A1), for protection of the reflective electrode layer, as shown in FIG. 5, each subpixel 32 further includes a reflective electrode protection layer 326 between the reflective electrode layer 323 and the microcavity underlayer 321. The reflective electrode protection layer 326 is made of corrosion-resistant conductive material, for example, indium tin oxide (ITO).

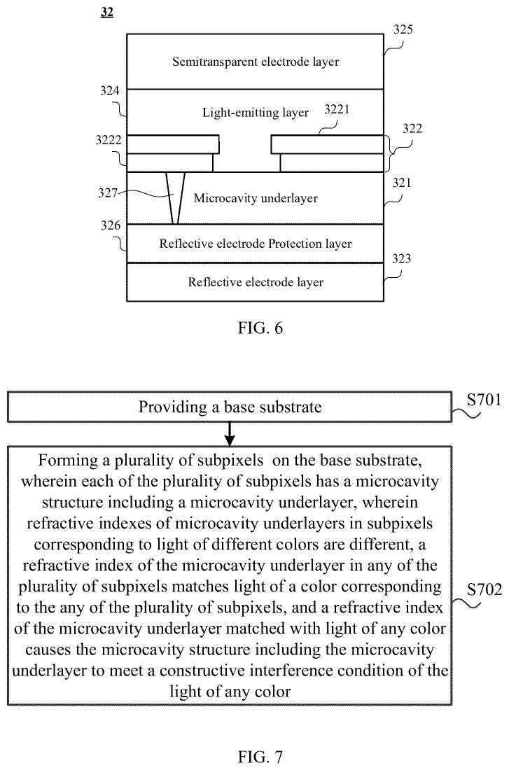

In general, the microcavity underlayer is not conductive. For electrical connection between the structures on two sides of the microcavity underlayer, as shown in FIG. 6, a via 327 is defined in the microcavity underlayer 321. A conductive material is filled in the via to electrically connect the structures on two sides of the microcavity underlayer. In some embodiments, in the case that the structures on two sides of the microcavity underlayer include the reflective electrode layer and the light-emitting layer, the conductive material in the via electrically connects the reflective electrode layer and the light-emitting layer. For example, in the case that the structures on two sides of the microcavity underlayer include the reflective electrode protection layer and the light-emitting layer, the conductive material in the via electrically connects the reflective electrode protection layer and the light-emitting layer. For example, in the case that the structures on two sides of the microcavity underlayer include the reflective electrode layer and the ITO layer, the conductive material in the via electrically connects the reflective electrode layer and the ITO layer.

In some embodiments, in the case that the via connects the structures on two sides of the microcavity underlayer, the taper of the via in the microcavity underlayer of each subpixel is less than a predetermined angle threshold. The predetermined angle threshold is controlled based on requirements and experience. In some embodiments, for abnormal lapping of the structures on two sides of the microcavity underlayer, the predetermined angle threshold is 45°.

Some embodiments of the present disclosure further provide a display device. The display device includes the display substrate according to the embodiments of the present disclosure. In some embodiments, the display device includes, but is not limited to, a mobile phone, a computer, a television, a game console, an automotive display, an electronic paper, a tablet, a laptop, a digital photo frame, and any other products or assemblies with the display function.

For reduction of the difference in the luminous efficacies of different subpixels and improvement of the display uniformity of the plurality of subpixels, as shown in FIG. 7, some embodiments of the present disclosure provide a method for manufacturing a display substrate corresponding to the display substrate according to the embodiments of the present disclosure. The method includes S701 to S702.

In S701, a base substrate is provided.

Prior to formation of the display substrate, the base substrate is first provided. The base substrate is a rigid base substrate or a flexible base substrate, which is not specifically limited in the present disclosure. In some embodiments, the base substrate includes a complementary metal-oxide-semiconductor (CMOS) base substrate.

In S702, a plurality of subpixels are formed on the base substrate, wherein each of the plurality of subpixels has a microcavity structure including a microcavity underlayer, wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure including the microcavity underlayer to meet a constructive interference condition of the light of any color.

In the process, the plurality of subpixels are formed on the base substrate. The refractive indexes of the microcavity underlayers in the plurality of subpixels are different, the refractive index of the microcavity underlayer in any of the plurality of subpixels matches a wavelength of the light of the color corresponding to the any of the plurality of subpixels, and the refractive index of the microcavity underlayer matched with light of any color causes the microcavity structure including the microcavity underlayer to meet the constructive interference condition of the light of any color. In some embodiments, the refractive index of the microcavity underlayer in the any subpixel and a wavelength of the light of the color corresponding to the any subpixel meet:

$$A + n \times d = k \times \frac{λ}{2} .$$

A represents the optical path in the microcavity structure other than the microcavity underlayer in the subpixel, and the microcavity structures of the plurality of subpixels have the same A. n represents the refractive index of the microcavity underlayer in the subpixel, d represents the thickness of the microcavity underlayer in the subpixel, k is a positive integer, and Λ represents the wavelength of the light of the color corresponding to the subpixel.

As such, as the refractive index of the microcavity underlayer matched with light of any color causes the microcavity structure including the microcavity underlayer to meet the constructive interference condition of the light of the color, the refractive index of the microcavity underlayer is adjusted to cause the microcavity structure of the subpixel to meet the constructive interference condition of the light of the corresponding color. Thus, compared with the method of adjusting the thickness of the microcavity underlayer, the refractive index of the microcavity underlayer is adjusted in the present disclosure, such that the difference in thicknesses of the microcavity underlayers in the plurality of subpixels with different wavelengths is reduced, the difference in the luminous efficiencies of different subpixels is reduced, and the display uniformity of the plurality of subpixels is improved.

In some embodiments, as shown in FIG. 8, S702 includes S801 to S803.

In S801, reflective electrode layers of the plurality of subpixels are formed on the base substrate.

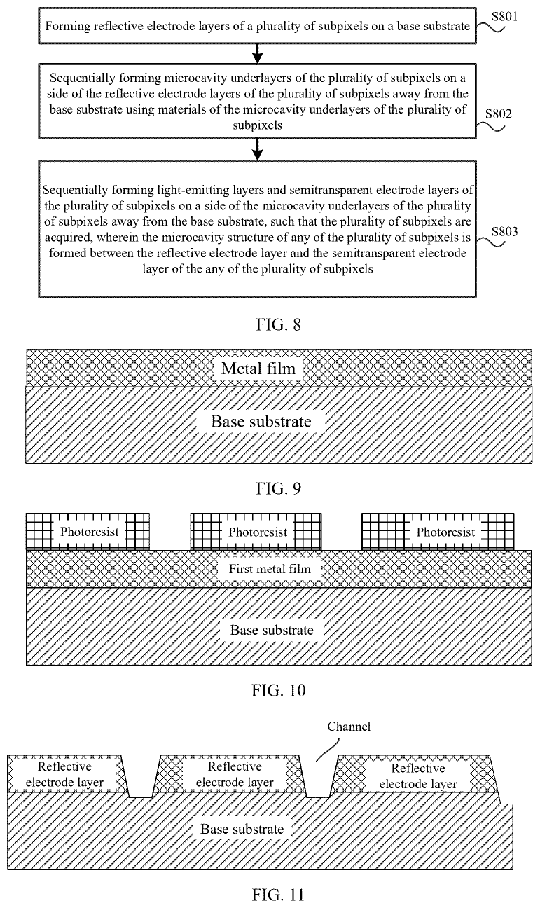

In some embodiments, thicknesses and/or refractive indexes of the reflective electrode layers of the plurality of subpixels are alternative the same. The reflective electrode layer is an anode layer or a cathode layer of the subpixel, which is not specifically limited in the present disclosure. In some embodiments, as shown in FIG. 9, a metal film is acquired by coating a metal film on the base substrate. For example, a metal, for example, Al, Ti, or Ag, is coated to acquire a metal film that totally reflects light. Upon formation of the metal film, the photoresist is evenly coated on the metal film, and then exposure, development, and etching are performed to acquire the reflective electrode layer.

Exposure refers to covering a mask on a metal film coated with photoresist and then irradiating light with a specific wavelength to the metal film covered with the mask. After the photoresist not covered by the mask plate is irradiated, the photosensitive agent in the photoresist undergoes the photochemical reaction. In the case that the photoresist is a positive photoresist, the chemical composition of the photoresist not covered by the mask plate changes after being irradiated and is soluble in the developer, and the chemical composition of the unirradiated photoresist is unchanged and insoluble in the developer. In the case that the photoresist is a negative photoresist, the chemical composition of the photoresist not covered by the mask plate changes after being irradiated and is insoluble in the developer, and the chemical composition of the unirradiated photoresist is unchanged and is soluble in the developer.

Upon irradiation, the photoresist on the metal film is cleaned with the developer, such that the photoresist on the metal film that is soluble in the developer is dissolved, and the photoresist that is insoluble in the developer is retained. As shown in FIG. 10, upon cleaning with the developer, part of the photoresist on the metal film is retained.

Upon cleaning with the developer, the metal film is further etched. Based on different use scenarios and requirements, different methods are used for etching. In some embodiments, dry etching is performed on regions of the metal film that are not covered by the photoresist. The dry etching include sputtering and ion beam milling, plasma etching, high pressure plasma etching, high density plasma etching, reactive ion etching, and the like. In some embodiments, wet etching is performed on regions of the metal film that are not covered by the photoresist. The wet etching refers to a method for removing regions not covered by the photoresist using the chemical reaction between the solution and the to-be-etched material to achieve etching. As shown in FIG. 11, upon etching of the metal film, the reflective electrode layers of different subpixels are acquired, and channels are present between adjacent reflective electrode layers.

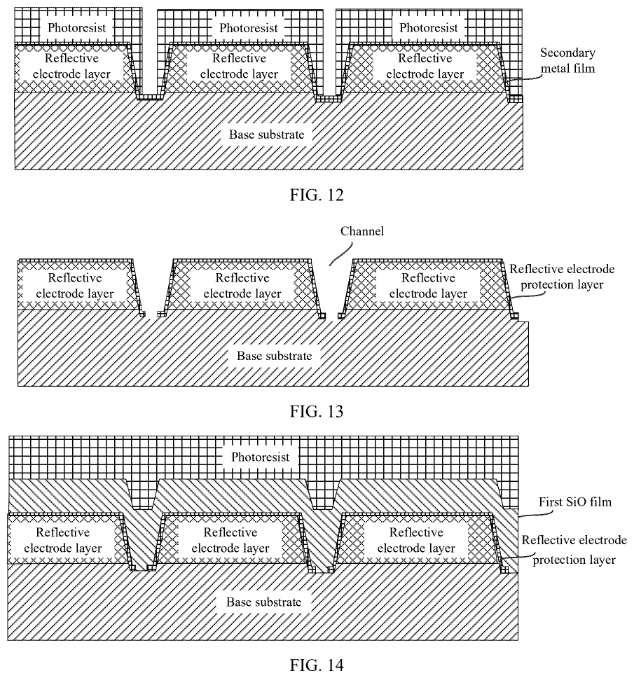

In some embodiments, in the case that the reflective electrode layer is made of a corrosion-prone material, such as aluminum, the reflective electrode protection layer is formed on the reflective electrode layer using a corrosion-resistant conductive material to protect the reflective electrode layer. In some embodiments, as shown in FIG. 12, the reflective electrode layer is coated with a corrosion-resistant conductive material to acquire a secondary metal film, and then the coated film is processed by adhesive coating, exposing, developing, and etching to form the reflective electrode protection layer on the reflective electrode layer. As shown in FIG. 13, a reflective electrode protection layer is formed on the reflective electrode layer. In some embodiments, the corrosion-resistant conductive material is ITO.

In S802, microcavity underlayers of the plurality of subpixels are sequentially formed on a side of the reflective electrode layers of the plurality of subpixels away from the base substrate using materials of the microcavity underlayers of the plurality of subpixels.

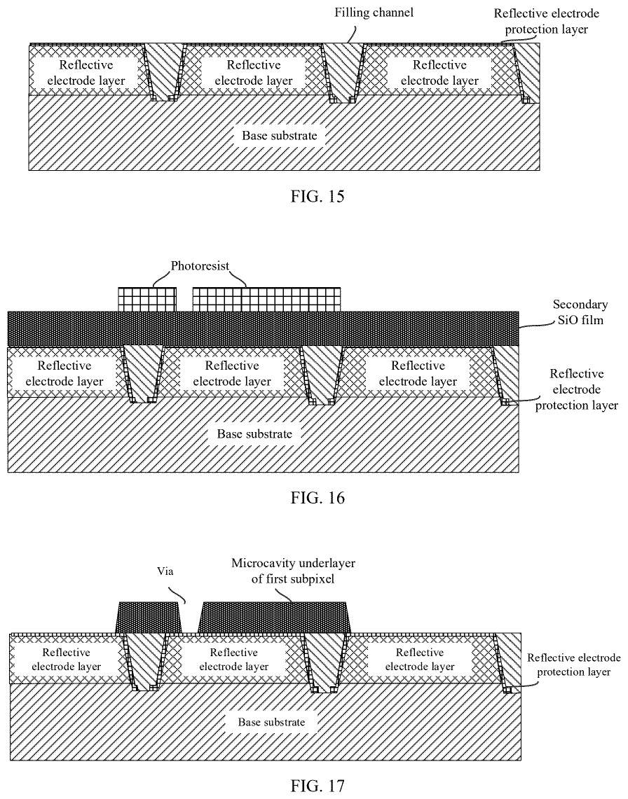

Upon acquisition of the reflective electrode layers of the plurality of subpixels, the microcavity underlayers of the plurality of subpixels are sequentially formed on the side of the reflective electrode layers of the plurality of subpixels away from the base substrate using the materials of the microcavity underlayers of the plurality of subpixels. As channels shown in FIG. 11 and FIG. 13 are formed in the etching process, the channels are filled prior to formation of the microcavity underlayers. In some embodiments, SiO is used to fill. For example, as shown in FIG. 14, SiO is coated on the base substrate including the reflective electrode layer, and then the channel is filled by adhesive coating, exposing, developing, and dry etching to acquire the display substrate as shown in FIG. 15, such that the transferring of the break difference of the reflective electrode layer on the semitransparent electrode layer.

Upon filling of the channel, the microcavity underlayers of the plurality of subpixels are sequentially formed on the side of the reflective electrode layers of the plurality of subpixels away from the base substrate using the materials of the microcavity underlayers of the plurality of subpixels. In some embodiments, the microcavity underlayers of the plurality of subpixels are sequentially formed on the side of the reflective electrode layers of the plurality of subpixels away from the base substrate using the materials of the microcavity underlayers of the plurality of subpixels in an ascending order of etching rates of the materials of the microcavity underlayers of the plurality of subpixels, such that the etching loss of a previously formed film layer forming a film layer.

Illustratively, the plurality of subpixels in the display substrate include a first subpixel and a second subpixel, and an etching rate in a material of a microcavity underlayer in the first subpixel is less than an etching rate in a material of a microcavity underlayer in the second subpixel. For example, a ratio of the etching rate in the material of the microcavity underlayer in the first subpixel to the etching rate in the material of the microcavity underlayer in the second subpixel is less than or equal to a predetermined ratio threshold. In some embodiments, the predetermined ratio threshold is 1:20. On this basis, the processing of sequentially forming the microcavity underlayers of the plurality of subpixels on the side of the reflective electrode layers of the plurality of subpixels away from the base substrate using the materials of the microcavity underlayers of the plurality of subpixels in the ascending order of the etching rates of the materials of the microcavity underlayers of the plurality of subpixels includes SA1 to SA2.

In SA1, a first material film is formed on the side of the reflective electrode layers of the plurality of subpixels away from the base substrate using the material of the microcavity underlayer in the first subpixel, and the microcavity underlayer in the first subpixel is formed by etching the first material film.

In some embodiments, the first material film is formed using the material of the microcavity underlayer in the first subpixel, and then the microcavity underlayer in the first subpixel is formed by adhesive coating, exposing, developing, and etching the first material film. As shown in FIG. 16, after the secondary SiO film is formed using SiO on the side including the reflective electrode protection layer away from the base substrate, the photoresist is used for exposing, developing, and etching, and the microcavity underlayer of the first subpixel shown in FIG. 17 is acquired. In some embodiments, in the process of forming the microcavity underlayer of the first subpixel, a via is formed in the microcavity underlayer of the first subpixel simultaneously. The taper of the via is less than 45°.

In SA2, a second material film is formed on the side of the reflective electrode layers of the plurality of subpixels away from the base substrate using the material of the microcavity underlayer in the second subpixel, and the microcavity underlayer in the second subpixel is formed by etching the second material film.

As the etching rate in the material of the microcavity underlayer in the first subpixel is less than the etching rate in the material of the microcavity underlayer in the second subpixel, the microcavity underlayer in the second subpixel is formed upon formation of the microcavity underlayer in the first subpixel to reduce the etching loss of the first subpixel.

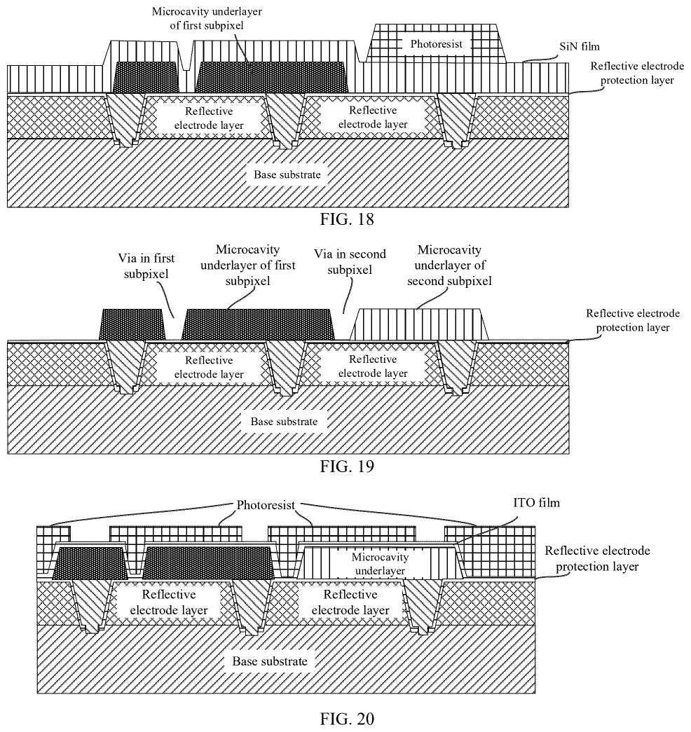

In some embodiments, the second material film is formed using the material of the microcavity underlayer in the second subpixel, and then the microcavity underlayer in the second subpixel is formed by adhesive coating, exposing, developing, and etching the second material film. As shown in FIG. 18, after the SiN film is formed using SiN on the base substrate including the microcavity underlayer in the first subpixel, the photoresist is used for exposing, developing, and etching, and the microcavity underlayer of the second subpixel shown in FIG. 19 is acquired. In some embodiments, in the process of forming the microcavity underlayer of the second subpixel, a via is formed in the microcavity underlayer of the second subpixel simultaneously. The taper of the via is less than 45°.

In some embodiments, the material of the microcavity underlayer in the first subpixel is silicon oxide, and the material of the microcavity underlayer in the second subpixel is silicon nitride. In this case, the silicon oxide film is formed first, the microcavity underlayer of the first subpixel is formed in the silicon oxide film by etching, a layer of silicon nitride film is formed, and the microcavity underlayer of the second subpixel is formed in the silicon nitride film by etching.

In some embodiments, the thicknesses of the microcavity underlayers in the plurality of subpixels are the same. Moreover, the materials of the microcavity underlayers in the subpixels corresponding to light of different colors are the same or different. For example, in the case that the materials of the microcavity underlayers in the subpixels corresponding to light of different colors are the same, different particles are doped in the microcavity underlayers in the subpixels corresponding to light of different colors to adjust the refractive indexes of the microcavity underlayers.

In S803, light-emitting layers and semitransparent electrode layers of the plurality of subpixels are sequentially formed on a side of the microcavity underlayers of the plurality of subpixels away from the base substrate, such that the plurality of subpixels are acquired, wherein the microcavity structure of any of the plurality of subpixels is formed between the reflective electrode layer and the semitransparent electrode layer of the any of the plurality of subpixels.

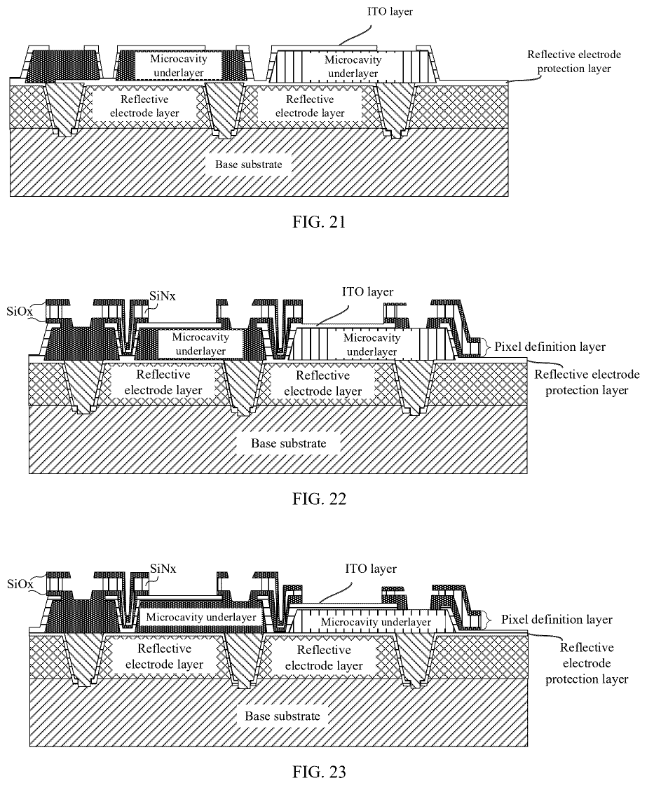

In some embodiments, upon acquisition of the structure shown in FIG. 19, a film is formed on a base substrate including the microcavity underlayer using a conductive material, and then a space of the subpixel is opened by adhesive exposing, developing, and dry etching. Meanwhile, as the conductive material is also deposited in the vias in the microcavity underlayers of the plurality of subpixels, the conductive material is electrically connected to the structures under the microcavity underlayers. For example, the conductive material is ITO. As shown in FIG. 20, an ITO film is formed on the surface of the microcavity underlayer and in the via. After exposure, development, and etching with the photoresist, the ITO layer shown in FIG. 21 is acquired.

For improvement of the stability of the subpixel structure, undercut structures of the plurality of subpixels are alternatively formed upon formation of the microcavity underlayers of the plurality of subpixels and prior to formation of the light-emitting layers and the semitransparent electrode layers of the plurality of subpixels. In some embodiments, the undercut structure includes a first material layer and a second material layer, and an etching rate in the first material layer is less than an etching rate in the second material layer. For example, the first material layer and the second material layer meet any of the following conditions: a material of the first material layer is the same as a material with a lowest etching rate in materials of the microcavity underlayers in the plurality of subpixels, and a material of the second material layer is different from the material with the lowest etching rate in the materials of the microcavity underlayers in the plurality of subpixels; and the material of the first material layer is different from a material with a highest etching rate in the materials of the microcavity underlayers in the plurality of subpixels, and the material of the second material layer is the same as the material with the highest etching rate in the materials of the microcavity underlayers in the plurality of subpixels.

In some embodiments, a second material film layer is formed on the side of the microcavity underlayers of the plurality of subpixels away from the base substrate using the material with the highest etching rate in the materials of the microcavity underlayers of the plurality of subpixels. Then, the first material film layer is formed on the side of the second material film layers of the plurality of subpixels away from the base substrate using the material with the lowest etching rate in the materials of the microcavity underlayers in the plurality of subpixels. Then, the first material film layer and the second material film layer of the plurality of subpixels are etched to form the undercut structures of the plurality of subpixels. The undercut structure includes a first material layer and a second material layer that are stacked, and the undercut structure includes a recess portion. An orthographic projection of the surface of the first material layer enclosing the recess portion on the base substrate is within an orthographic projection of the surface of the second material layer enclosing the recess portion on the base substrate.

Illustratively, the material with the highest etching rate in the materials of the microcavity underlayers in the plurality of subpixels is SiNx, and the material with the lowest etching rate in the materials of the microcavity underlayers in the plurality of subpixels is SiOx. Thus, a SiNx material layer is formed on the side of the microcavity underlayers of the plurality of subpixels away from the base substrate using SiNx, and then a SiOx material layer is formed on the side of the SiNx material layer away from the base substrate using SiOx. Then, the SiNx material layer of each subpixel is opened with the etching solution, and the SiOx material layer is etched inward with the etching solution to form the undercut structure with small top and large bottom.

In some embodiments, SiOx, SiNx, and SiOx are sequentially coated on the base substrate including the microcavity underlayer for a composite film layer, and then the pixel definition layer (PDL) in the pixel is opened by adhesive coating, exposing, developing, and dry etching. The etching is performed in four steps. In the first step, carbon tetrafluoride (CF4) is used to etch the PDL above the pixel. In the second step, the etched critical dimension (CD) in the subpixel is enlarged by the transverse de-adhesive method. In the third step, CF4 is used to open the top SiOx layer according to the time mode. In the fourth step, sulfur hexafluoride (SF6) is used to perform lateral and inward etching. As an etching selection ratio of SiOx/SiNx is at least greater than 7 by SF6, the undercut structure is acquired by lateral and inward etching using SF6. Based on the step, a lateral leakage cutoff (LLC) inward etching structure to-be-footed is formed on the footing, and the pixel definition layer is formed. FIG. 22 is a schematic diagram of formation of a pixel definition layer on a microcavity underlayer, and the pixel definition layer is the undercut structure.

Based on the above embodiments, the thicknesses of the microcavity underlayers in the subpixels corresponding to light of different colors are the same or different in the present disclosure. FIG. 22 is a schematic diagram of microcavity underlayers with the same thickness in subpixels corresponding to light of different colors. FIG. 23 is a schematic diagram of microcavity underlayers with different thicknesses in subpixels corresponding to light of different colors.

Upon formation of the pixel definition layer, the light-emitting layers and the semitransparent electrode layers of the plurality of subpixels are formed on the base substrate including the pixel definition layer. The microcavity structure is formed between the reflective electrode layer of any subpixel and the semitransparent electrode layer of the subpixel. For example, a light-emitting material is filmed on the base substrate including the pixel definition layer, and then the light-emitting layers of the plurality of subpixels are acquired by adhesive coating, exposing, developing, and dry etching. Then, a conductive material is used to form a film on the base substrate including the light-emitting layer, and then the semitransparent electrode layer is acquired by adhesive coating, exposing, developing, and dry etching. In some embodiments, the thicknesses and/or refractive indexes of the light-emitting layers in the plurality of subpixels are alternatively the same, and the thicknesses and/or refractive indexes of the semitransparent electrode layers in the plurality of subpixels are alternatively the same.

Upon the above process, the display panel further includes a peripheral region surrounding the subpixels. The peripheral region includes a first silicon oxide layer, a first silicon nitride layer, a second silicon nitride layer, and a second silicon oxide layer. The first silicon oxide layer and the microcavity underlayer in the first subpixel are disposed on the same layer, that is, the first silicon oxide layer is acquired in forming the microcavity underlayer in the first subpixel. The first silicon nitride layer and the microcavity underlayer in the second subpixel are disposed on the same layer, that is, the first silicon nitride layer is acquired in forming the microcavity underlayer in the second subpixel. The second silicon nitride layer and the second material layer are disposed on the same layer, that is, the second silicon nitride layer is acquired in forming the second material layer. The second silicon oxide layer and the first material layer are disposed on the same layer, that is, the second silicon oxide layer is acquired in forming the first material layer.

In the embodiments of the present disclosure, the refractive index of the microcavity underlayer matched with light of any color causes the microcavity structure including the microcavity underlayer to meet the constructive interference condition of the light of the color. That is, the refractive index of the microcavity underlayer is adjusted to cause the microcavity structure of the subpixel to meet the constructive interference condition of the light of the corresponding color. Thus, compared with the method of adjusting the thickness of the microcavity underlayer, the refractive index of the microcavity underlayer is adjusted in the present disclosure, such that the thickness of the microcavity underlayer is reduced, the difference in thicknesses of the microcavity underlayers in the plurality of subpixels corresponding to light of different colors is reduced, the difference in the luminous efficiencies of different subpixels is reduced, and the display uniformity of the plurality of subpixels is improved.

It should be noted that in the description, relational terms, such as first, second, and the like, are used only to distinguish one entity or operation from another entity or operation, and are not intended to require or imply any actual relationship or order between the entities or operations. Furthermore, the term “includes,” “contains,” or variations thereof is intended to cover non-exclusive inclusion, such that a process, a method, an object, or a device including a set of elements includes those elements and further includes other elements not expressly listed, or includes elements inherent to the process, the method, the object, or the device. Without further restrictions, the element limited by “including a . . . ” does not exclude additional the same element in the process, the method, the object, or the device that includes the element.

Various embodiments in the description are described in the related manner. Thus, the same and similar parts of the embodiments can be referred to each other, and each embodiment focuses on the difference from other embodiments. In particular, the method embodiments are basically similar to the method embodiments, and thus the description is relatively simple, and the relevant descriptions can be referred to partial description of the method embodiments.

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

1. A display substrate, comprising:
a base substrate; and
a plurality of subpixels on the base substrate, each of the plurality of subpixels having a microcavity structure comprising a microcavity underlayer, wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure comprising the microcavity underlayer to meet a constructive interference condition of the light of any color.

2. The display substrate according to claim 1, wherein the refractive index of the microcavity underlayer in the any of the plurality of subpixels and a wavelength of the light of the color corresponding to the any of the plurality of subpixels meet:
$$A + n \times d = k \times \frac{λ}{2} ;$$
wherein A represents an optical path in the microcavity structure other than the microcavity underlayer in the any of the plurality of subpixels, the microcavity structures of the plurality of subpixels have a same A, n represents the refractive index of the microcavity underlayer in the any of the plurality of subpixels, d represents a thickness of the microcavity underlayer in the any of the plurality of subpixels, k is a positive integer, and Λ represents the wavelength of light of the color corresponding to the any of the plurality of subpixels.

3. The display substrate according to claim 1, wherein thicknesses of the microcavity underlayers in the plurality of subpixels are the same.

4. The display substrate according to claim 1, wherein materials of the microcavity underlayers in the subpixels corresponding to the light of different colors are the same or different.

5. The display substrate according to claim 4, wherein in a case that the materials of the microcavity underlayers in the subpixels corresponding to the light of different colors are the same, different particles are doped in the microcavity underlayers in the subpixels corresponding to the light of different colors.

6. The display substrate according to claim 1, wherein each of the plurality of subpixels further comprises an undercut structure on a side of the microcavity underlayer in the each of the plurality of subpixels away from the base substrate, wherein the undercut structure comprises a recess portion, and the undercut structure comprises a first material layer and a second material layer, wherein the first material layer is disposed on a side of the second material layer away from the base substrate, and an orthographic projection of a surface of the first material layer enclosing the recess portion on the base substrate is within an orthographic projection of a surface of the second material layer enclosing the recess portion on the base substrate.

7. The display substrate according to claim 6, wherein an etching rate in the first material layer is less than an etching rate in the second material layer.

8. The display substrate according to claim 7, wherein the first material layer and the second material layer meet any of the following conditions:
a material of the first material layer is the same as a material with a lowest etching rate in materials of the microcavity underlayers in the plurality of subpixels, and a material of the second material layer is different from the material with the lowest etching rate in the materials of the microcavity underlayers in the plurality of subpixels; and
the material of the first material layer is different from a material with a highest etching rate in the materials of the microcavity underlayers in the plurality of subpixels, and the material of the second material layer is the same as the material with the highest etching rate in the materials of the microcavity underlayers in the plurality of subpixels.

9. The display substrate according to claim 6, wherein the plurality of subpixels comprise a first subpixel and a second subpixel, wherein the first subpixel is a blue subpixel, and the second subpixel is a green subpixel; a material of a microcavity underlayer in the first subpixel comprises silicon oxide, and a material of a microcavity underlayer in the second subpixel comprises silicon nitride; and a material of the first material layer comprises silicon oxide, and a material of the second material layer comprises silicon nitride.

10. The display substrate according to claim 1, further comprising: a peripheral region surrounding the plurality of subpixels; wherein the peripheral region comprises a first silicon oxide layer, a first silicon nitride layer, a second silicon nitride layer, and a second silicon oxide layer that are sequentially stacked; and
the plurality of subpixels comprise a first subpixel and a second subpixel, and each of the plurality of subpixels further comprises an undercut structure on a side of the microcavity underlayer in the each of the plurality of subpixels away from the base substrate, wherein the undercut structure comprises a recess portion, and the undercut structure comprises a first material layer and a second material layer, wherein the first material layer is disposed on a side of the second material layer away from the base substrate, and an orthographic projection of a surface of the first material layer enclosing the recess portion on the base substrate is within an orthographic projection of a surface of the second material layer enclosing the recess portion on the base substrate;
wherein the first silicon oxide layer and a microcavity underlayer in the first subpixel are disposed on a same layer, the first silicon nitride layer and a microcavity underlayer in the second subpixel are disposed on a same layer, the second silicon nitride layer and the second material layer are disposed on a same layer, and the second silicon oxide layer and the first material layer are disposed on a same layer.

11. The display substrate according to claim 6, wherein each of the plurality of subpixels further comprises:
a reflective electrode layer between the base substrate and the microcavity underlayer;
a reflective electrode protection layer between the reflective electrode layer and the microcavity underlayer; and
a light-emitting layer and a semitransparent electrode layer that are sequentially stacked on a side of the undercut structure away from the base substrate;
wherein the microcavity structure of each of the plurality of subpixels is formed between the reflective electrode layer and the semitransparent electrode layer, and the plurality of subpixels meet: a condition that thicknesses, refractive indexes, or both of the reflective electrode layers in the plurality of subpixels are the same, a condition that thicknesses, refractive indexes, or both of the light-emitting layers in the plurality of subpixels are the same, a condition that thicknesses, refractive indexes, or both of the semitransparent electrode layers in the plurality of subpixels are the same, or any combination of the conditions.

12. The display substrate according to claim 1, wherein a via is defined in the microcavity underlayer in each of the plurality of subpixels, wherein a conductive material is filled in the via, the conductive material being configured to electrically connect structures on two sides of the microcavity underlayer.

13. The display substrate according to claim 12, wherein a taper of the via is less than 45°.

14. A display device, comprising: a display substrate, wherein the display substrate comprises:
a base substrate; and
a plurality of subpixels each having a microcavity structure, wherein the plurality of subpixels are disposed on the base substrate, and the microcavity structure in each of the plurality of subpixels comprises a microcavity underlayer, wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure comprising the microcavity underlayer to meet a constructive interference condition of the light of any color.

15. A method for manufacturing a display substrate, comprising:
providing a base substrate; and
forming a plurality of subpixels on the base substrate, each of the plurality of subpixels having a microcavity structure comprising a microcavity underlayer, wherein refractive indexes of microcavity underlayers in subpixels corresponding to light of different colors are different, a refractive index of the microcavity underlayer in any of the plurality of subpixels matches light of a color corresponding to the any of the plurality of subpixels, and a refractive index of the microcavity underlayer matched with light of any color causes the microcavity structure comprising the microcavity underlayer to meet a constructive interference condition of the light of any color.

16. The method according to claim 15, wherein forming the plurality of subpixels on the base substrate comprises:
forming reflective electrode layers of the plurality of subpixels on the base substrate;
sequentially forming the microcavity underlayers of the plurality of subpixels on a side of the reflective electrode layers of the plurality of subpixels away from the base substrate using materials of the microcavity underlayers of the plurality of subpixels; and
sequentially forming light-emitting layers and semitransparent electrode layers of the plurality of subpixels on a side of the microcavity underlayers of the plurality of subpixels away from the base substrate, such that the plurality of subpixels are acquired, wherein the microcavity structure of any of the plurality of subpixels is formed between the reflective electrode layer and the semitransparent electrode layer of the any of the plurality of subpixels.

17. The method according to claim 16, wherein sequentially forming the microcavity underlayers of the plurality of subpixels on the side of the reflective electrode layers of the plurality of subpixels away from the base substrate using the materials of the microcavity underlayers of the plurality of subpixels comprises:
sequentially forming the microcavity underlayers of the plurality of subpixels on the side of the reflective electrode layers of the plurality of subpixels away from the base substrate using the materials of the microcavity underlayers of the plurality of subpixels in an ascending order of etching rates of the materials of the microcavity underlayers of the plurality of subpixels.

18. The method according to claim 17, wherein the plurality of subpixels comprise a first subpixel and a second subpixel, and an etching rate in a material of a microcavity underlayer in the first subpixel is less than an etching rate in a material of a microcavity underlayer in the second subpixel; and sequentially forming the microcavity underlayers of the plurality of subpixels on the side of the reflective electrode layers of the plurality of subpixels away from the base substrate using the materials of the microcavity underlayers of the plurality of subpixels in the ascending order of the etching rates of the materials of the microcavity underlayers of the plurality of subpixels comprises:
forming a first material film on the side of the reflective electrode layers of the plurality of subpixels away from the base substrate using the material of the microcavity underlayer in the first subpixel;
forming the microcavity underlayer in the first subpixel by etching the first material film;
upon forming the microcavity underlayer in the first subpixel, forming a second material film on the side of the reflective electrode layers of the plurality of subpixels away from the base substrate using the material of the microcavity underlayer in the second subpixel; and
forming the microcavity underlayer in the second subpixel by etching the second material film.

19. The method according to claim 18, wherein a ratio of the etching rate in the material of the microcavity underlayer in the first subpixel to the etching rate in the material of the microcavity underlayer in the second subpixel is less than or equal to a predetermined ratio threshold; and the material of the microcavity underlayer in the first subpixel comprises silicon oxide, and the material of the microcavity underlayer in the second subpixel comprises silicon nitride.

20. The method according to claim 16, wherein upon sequentially forming the microcavity underlayers of the plurality of subpixels on the side of the reflective electrode layers of the plurality of subpixels away from the base substrate using the materials of the microcavity underlayers of the plurality of subpixels, and prior to sequentially forming the light-emitting layers and the semitransparent electrode layers of the plurality of subpixels on the side of the microcavity underlayers of the plurality of subpixels away from the base substrate, the method further comprises:
forming second material layers on the side of the microcavity underlayers of the plurality of subpixels away from the base substrate using a material with a highest etching rate in the materials of the microcavity underlayers in the plurality of subpixels;
forming first material layers on the side of the second material layers of the plurality of subpixels away from the base substrate using a material with a lowest etching rate in the materials of the microcavity underlayers in the plurality of subpixels; and
forming undercut structures of the plurality of subpixels by etching the first material layers and the second material layers of the plurality of subpixels, wherein each of the undercut structures comprises a recess portion, and an orthographic projection of a surface of each of the first material layers enclosing the recess portion on the base substrate is within an orthographic projection of a surface of one of the second material layers enclosing the recess portion on the base substrate.
